(19) United States
(12) Patent Application Publication
(10) Pub. No.: US 2008/0056038 A1
(43) Pub. Date: Mar. 6, 2008

(54) Semiconductor memory device

(75) Inventor: Hoe-Kwon Jeong, Kyoungki-do (KR)

Correspondence Address: MCDERMOTT WILL & EMERY LLP, 600 13TH STREET, N.W., WASHINGTON, DC, 20005-3096, US

(73) Assignee: HYNIX SEMICONDUCTOR INC.

(21) Appl. No.: 11/819,817

(22) Filed: Jun. 26, 2007

(30) Foreign Application Priority Data
Aug. 31, 2006 (KR) 2006-0083740

(51) Int. Cl. G11C 7/00; G11C 7/10

(52) U.S. Cl. 365/203; 365/189.05

(57) ABSTRACT

A semiconductor memory device is able to control a timing of an auto-precharge operation. The semiconductor memory device includes a timing controller and an auto-precharge controller. The timing controller generates timing control signals to be used for controlling a timing of an auto-precharge operation based on control signals inputted from an external device or through a mode register set. The auto-precharge controller controls the auto-precharge operation in response to the timing control signals.

### CROSS-REFERENCE TO RELATED APPLICATIONS

The present invention claims priority of Korean patent application no. 10-2006-0083740, filed in the Korean Patent Office on Aug. 31, 2006, which is incorporated by reference in its entirety.

### BACKGROUND OF THE INVENTION

The present invention relates to a semiconductor memory device, more particularly, to a semiconductor memory device for controlling a timing of an auto-precharge operation.

A semiconductor memory device stores a plurality of data and outputs a required one of the plurality of data. Accordingly, the semiconductor memory device mainly performs a write operation for storing data and a read operation for outputting data selected among the stored data. Additionally, the semiconductor memory device performs a precharge operation for preparing a subsequent read/write operation when the read/write operation is not performed. Furthermore, a semiconductor memory device employing a capacitor as a data storage unit, such as a dynamic random access memory (DRAM), performs a refresh operation for compensating charge leakage from the capacitor.

The semiconductor memory device is provided with memory cells that are basic units in a matrix form to store a plurality of data efficiently. A plurality of word lines and bit lines are respectively formed in the direction of row and column in the matrix form. The memory cells are arranged at respective intersections of the plurality of word lines and bit lines. The word line is activated in response to a row address and the bit line is activated in response to a column address.

For the read/write operation, one of the plurality of word lines is selected by the corresponding row address firstly and then one of the plurality of bit lines is selected by the corresponding column address. For the memory cell corresponding to the selected word line and bit line, a data I/O operation is performed.

As described above, the semiconductor memory device performs the precharge operation when there is no data access operation. Control circuits of the semiconductor memory device are reset to have a default value during the precharge operation, thereby preparing the subsequent read/write operation.

While the precharge operation is performed in response to an external precharge command, the precharge operation is also performed automatically when a predetermined number of clocks are counted from the read/write operation. The precharge operation which is automatically performed after an internally predetermined period without the external precharge command is called an auto-precharge operation. A semiconductor memory device internally generates an auto-precharge command in order to control the auto-precharge operation performed after a predetermined time passes from the input of a read or a write command.

Generally, since a timing for performing the auto-precharge operation is determined when designing a semiconductor memory device, it is required to re-design the semiconductor memory device to change the timing for the auto-precharge operation.

### SUMMARY OF THE INVENTION

Embodiments of the present invention are directed to providing a semiconductor memory device for being able to control a timing of an auto-precharge operation.

In accordance with an aspect of the present invention, a semiconductor memory device includes a timing controller for generating timing control signals to be used for controlling a timing of an auto-precharge operation based on control signals and an auto-precharge controller for controlling the auto-precharge operation in response to the timing control signals, wherein the control signals are inputted from an external device or through a mode register set (MRS)

### BRIEF DESCRIPTION OF THE DRAWINGS

FIG. 1 is a signal timing diagram illustrating an operation of a semiconductor memory device.

FIG. 2 is a block diagram of an auto-precharge controller in a semiconductor memory device.

FIG. 3 is a block diagram of a semiconductor memory device in accordance with the present invention.

FIG. 4 is a schematic circuit diagram of a timing controller described in FIG. 3.

FIG. 5 is a signal timing diagram illustrating an operation of the semiconductor memory device described in FIG. 3 with a parameter tDPL having a one-clock value 1CLK.

FIG. 6 is a signal timing diagram illustrating an operation of the semiconductor memory device described in FIG. 3 with a parameter tDPL having a two-clock value 2CLK.

FIG. 7 is a signal timing diagram illustrating an operation of the semiconductor memory device described in FIG. 3 with a parameter tDPL having a three-clock value 3CLK.

FIG. 8 is a signal timing diagram showing a simulation result of an operation of the semiconductor memory device described in FIG. 3.

### DESCRIPTION OF SPECIFIC EMBODIMENTS

A semiconductor memory device in accordance with the present invention is able to control a timing of an auto-precharge operation. Accordingly, it is easy to test an operation of the semiconductor memory device because the operation may be performed in response to a variety of parameter values. Therefore, a more reliable semiconductor memory device can be manufactured.

Hereinafter, a semiconductor memory device in accordance with the present invention will be described in detail referring to the accompanying drawings.

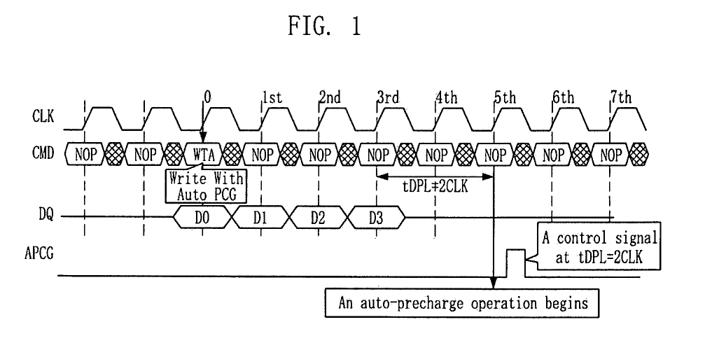

FIG. 1 is a signal timing diagram illustrating an operation of a semiconductor memory device.

For a write or a read operation accompanied by an auto-precharge operation, a write/auto-precharge command or a read/auto-precharge command is generated and inputted in synchronization with a clock signal CLK. In an embodiment of FIG. 1, a write/auto-precharge command WTA is inputted for a write operation accompanied by an auto-precharge operation. A semiconductor memory device receives and stores corresponding data D0 to D3. After the last data D3 is inputted, a control signal APCG is generated 2 clocks later. The auto-precharge operation is performed according to the control signal APCG.

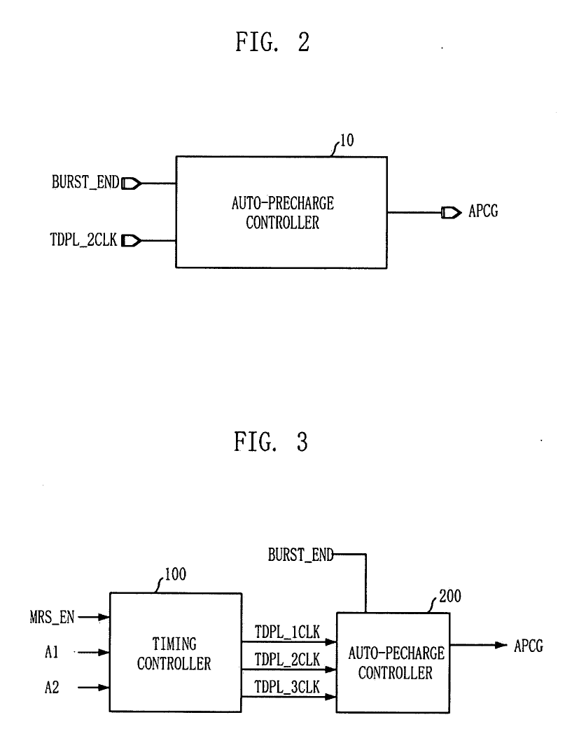

FIG. 2 is a block diagram of an auto-precharge controller 10 in the semiconductor memory device. The auto-precharge controller 10 generates a control signal APCG in response to a timing control signal TDPL_2CLK and a burst end signal BURST_END. The timing control signal TDPL-2CLK is outputted from a mode register set (MRS) setting circuit. The burst end signal BURST_END is a signal for indicating the end of a burst length. The burst length means the number of data which are continuously inputted/outputted according to one read/write command. The burst end signal BURST_END indicates an input/output timing of the last data.

When a write/auto-precharge command WTA is inputted, a write operation is performed for a time given as a burst length. After a predetermined time tDPL passes from the end of the write operation, a precharge operation is performed by a pulse of the control signal APCG. During the precharge operation, voltages on a bit line pair are reset to a voltage level of a precharge voltage and a subsequent read/write operation is prepared. The write operation and the auto-precharge operation are performed according to one command.

Among specifications with reference to operation timings of a semiconductor memory device, a parameter tDPL (data-in to precharge command) indicates a minimum time taken for an input data to be stored in a memory cell. Accordingly a precharge operation should be performed after a time corresponding to the parameter tDPL passes from an input timing of a data to be written. Generally, a semiconductor memory device needs a time corresponding to 2 clocks at least to store the data. As described in an embodiment shown in FIG. 1, a string of data D0 to D3 corresponding to one write command is inputted and it additionally needs a time corresponding to 2 clocks for the last data D3 to be stored. After the time passed, the control signal APCG is generated and the auto-precharge operation is performed according to the control signal APCG.

The timing control signal TDPL_2CLK is provided to a semiconductor memory device, wherein a parameter tDPL has a period corresponding to 2 clocks. When the timing control signal TDPL_2CLK is enabled in a logic high level, the control signal APCG is generated 2 clocks later on the basis of an activation timing of the burst end signal BURST_END at the auto-precharge controller 10 in FIG. 2.

As described above, a semiconductor memory device performs an auto-precharge operation after predetermined clocks from the input of a last data according to a write/auto-precharge command WTA. Therefore, it is difficult to change a timing of an auto-precharge operation.

FIG. 3 is a block diagram of a semiconductor memory device in accordance with a specific embodiment of the present invention. The semiconductor memory device includes a timing controller 100 for generating timing controlling signals to control a timing of an auto-precharge operation based on a setting value of a mode register set (MRS), and an auto-precharge controller 200 for controlling the auto-precharge operation in response to the timing controlling signals.

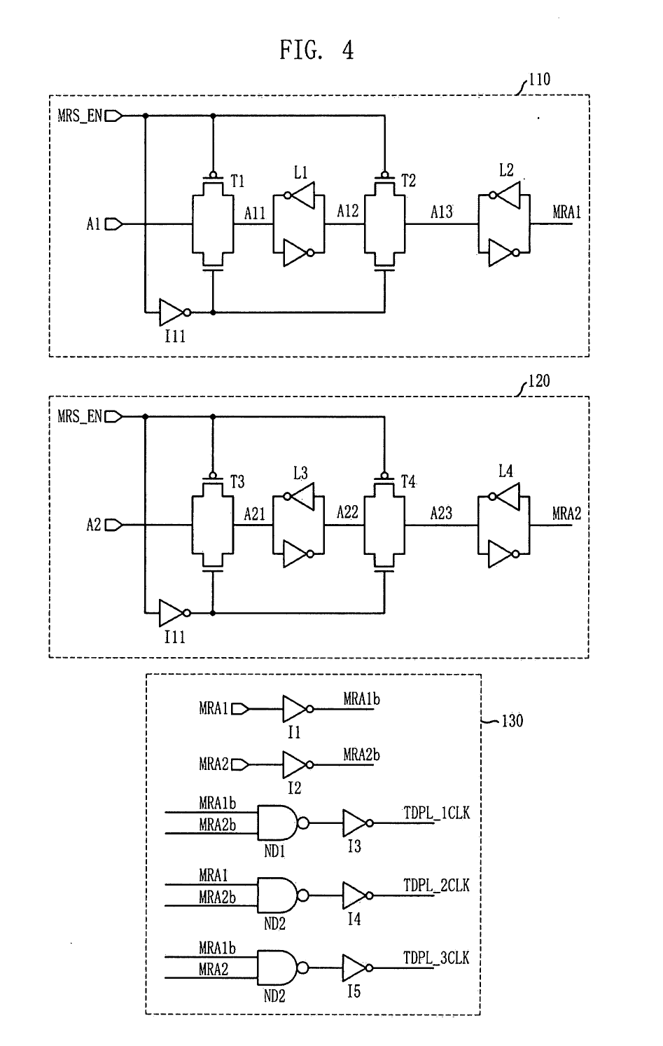

FIG. 4 is a schematic circuit diagram of the timing controller 100 described in FIG. 3. The timing controller 100 includes a first latch unit 110, a second latch unit 120 and a decoding unit 130.

The first latch unit 110 latches a first setting value A1 of the MRS in response to an enable signal MRS_EN. The second latch unit 120 latches a second setting value A2 of the MRS in response to the enable signal MRS_EN. The decoding unit 130 outputs a plurality of timing control signals TDPL_1CLK, TDPL_2CLK and TDPL_3CLK by decoding outputs of the first latch unit 110 and the second latch unit 120.

The first latch unit 110 includes a first transmission gate T1, a second transmission gate T2, a first latch L1 and a second latch L2. The first transmission gate T1 transmits the first setting value A1 in response to the enable signal MRS_EN. The first latch L1 latches an output of the first transmission gate T1. The second transmission gate T2 transmits an output of the first latch L1 in response to the enable signal MRS_EN. The second latch L2 latches an output of the second transmission gate T2.

The second latch unit 120 includes a third transmission gate T3, a fourth transmission gate T4, a third latch L3 and a fourth latch L4. The third transmission gate T3 transmits the second setting value A2 in response to the enable signal MRS_EN. The third latch L3 latches an output of the third transmission gate T3. The fourth transmission gate T4 transmits an output of the third latch L3 in response to the enable signal MRS_EN. The fourth latch L4 latches an output of the fourth transmission gate T4.

The decoding unit 130 includes two inverters and three logic gates. A first inverter I1 and a second inverter I2 invert the outputs of the first latch unit 110 and the second latch unit 120, respectively.

A first logic gate is provided with a first NAND logic gate ND1 and a third inverter I3. The first logic gate performs an AND operation on outputs of the first inverter I1 and the second inverter I2, thereby outputting a first timing control signal TDPL_1CLK. In response to the first timing control signal TDPL_1CLK, the auto-precharge operation is performed one clock later from the input of data corresponding to a write command.

A second logic gate is provided with a second NAND logic gate ND2 and a fourth inverter I4. The second logic gate performs an AND operation on outputs of the first latch unit 110 and the second inverter I2, thereby outputting a second timing control signal TDPL_2CLK. In response to the second timing control signal TDPL_2CLK, the auto-precharge operation is performed two clocks later from the input of data corresponding to the write command.

A third logic gate is provided with a third NAND logic gate ND3 and a fifth inverter I5. The third logic gate performs an AND operation on outputs of the first inverter I1 and the second latch unit 120, thereby outputting a third timing control signal TDPL_3CLK. In response to the third timing control signal TDPL_3CLK, the auto-precharge operation is performed three clocks later from the input of data corresponding to the write command.

At a write operation accompanied by an auto-precharge operation in a semiconductor memory device of the present invention, a value of a parameter tDPL is changeable according to the needs by changing a code of the MRS for the parameter tDPL. In an embodiment of the present invention, the parameter tDPL ranges from one clock to three clocks. Accordingly, three timing control signals TDPL_1CLK, TDPL_2CLK and TDPL_3CLK are generated.

The first latch unit 110 and the second latch unit 120 latch the setting values A1 and A2 while the enable signal MRS_EN has a logic high level and output signals MRA1 and MRA2, respectively. The decoding unit 130 outputs the three timing control signals TDPL_1CLK, TDPL_2CLK and TDPL_3CLK to the auto-precharge controller 200 according to the logic levels of the signals MRA1 and MRA2.

The auto-precharge controller 200 outputs a control signal APCG delayed by one of one clock 1CLK, two clocks 2CLK and three clocks 3CLK according to the logic levels of the timing control signals TDPL_1CLK, TDPL_2CLK and TDPL_3CLK. Accordingly, the semiconductor memory device in accordance with the present invention may be applied with a parameter tDPL having a variety of clock values 1CLK, 2CLK and 3CLK according to the setting values of the MRS. In accordance with another embodiment of the present invention, the parameter tDPL can also have a four- or five-clock value, 4CLK or 5CLK, by modifying the setting value of the MRS or a structure of the timing controller 100.

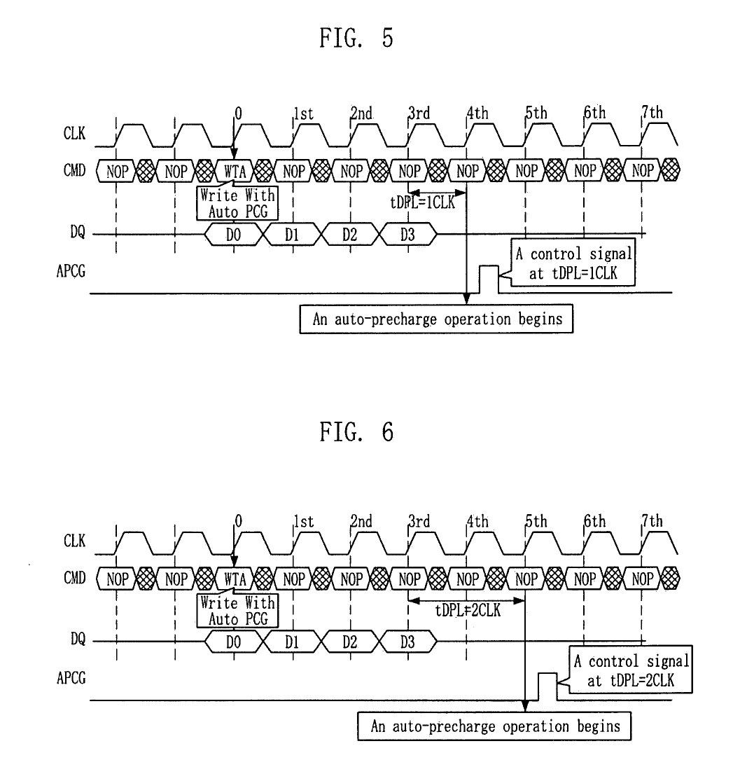

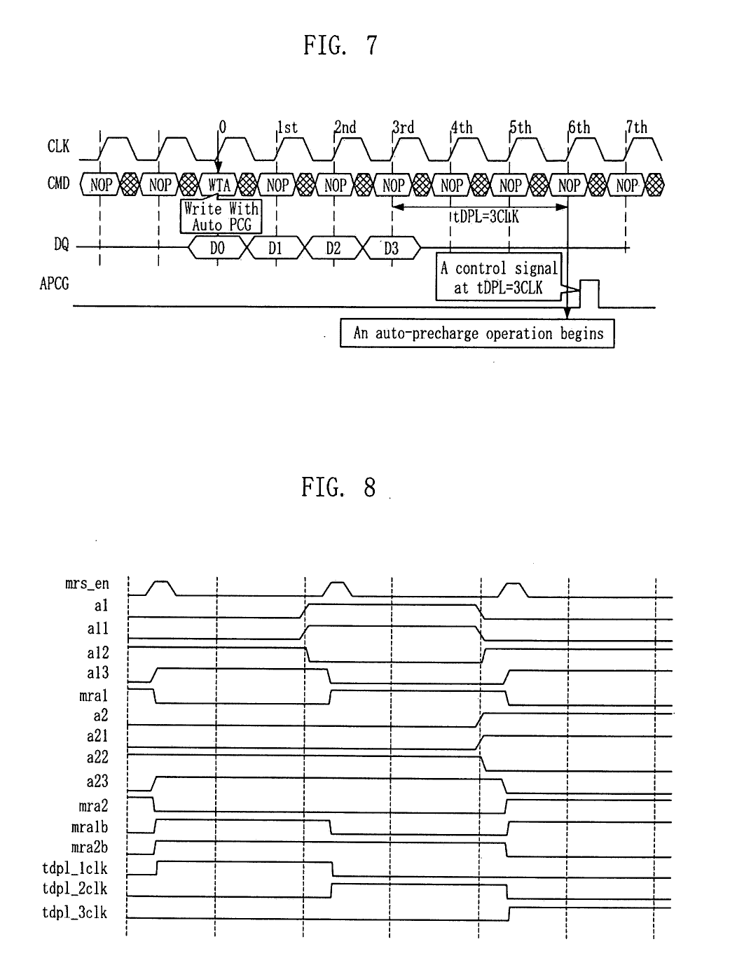

FIGS. 5 to 7 are signal timing diagrams illustrating the operation of the semiconductor memory device described in FIG. 3. The auto-precharge operations described in FIGS. 5 to 7 are performed by control signals APCG delayed as long as one clock 1CLK to three clocks 3CLK, respectively.

FIG. 8 is a signal timing diagram showing a simulation result of an operation of the semiconductor memory device described in FIG. 3. The timing control signals TDPL_1CLK, TDPL_2CLK and TDPL_3CLK are generated according to the logic levels of the first setting value A1 and the second setting value A2.

While the present invention has been described with respect to the particular embodiments, it will be apparent to those skilled in the art that various changes and modifications may be made without departing from the spirit and scope of the invention as defined in the following claims.

What is claimed is:

1. A semiconductor memory device, comprising:
a timing controller for generating timing control signals to be used for controlling a timing of an auto-precharge operation based on control signals; and
an auto-precharge controller for controlling the auto-precharge operation in response to the timing control signals,
wherein the control signals are inputted from an external device or through a mode register set (MRS).

2. The semiconductor memory device of claim 1, wherein the timing controller for generating the timing control signals by decoding the control signals.

3. The semiconductor memory device of claim 2, wherein the timing controller includes:
a first latch unit for latching a first setting value of the MRS in response to an enable signal;
a second latch unit for latching a second setting value of the MRS in response to the enable signal; and
a decoding unit for outputting the timing control signals by decoding outputs of the first latch unit and the second latch unit.

4. The semiconductor memory device of claim 3, wherein the auto-precharge controller outputs a control signal after a given number of clocks from input time of data corresponding a write command, wherein the number of clocks corresponds to the timing control signals.

5. The semiconductor memory device of claim 3, wherein the first latch unit includes:
a first transmission gate for transmitting the first setting value in response to the enable signal;
a first latch for latching an output of the first transmission gate;
a second transmission gate for transmitting an output of the first latch in response to the enable signal; and
a second latch for latching an output of the second transmission gate.

6. The semiconductor memory device of claim 3, wherein the second latch unit includes:
a third transmission gate for transmitting the second setting value in response to the enable signal;
a third latch for latching an output of the third transmission gate;
a fourth transmission gate for transmitting an output of the third latch in response to the enable signal; and
a fourth latch for latching an output of the fourth transmission gate.

7. The semiconductor memory device of claim 3, wherein the decoding unit includes:
a first inverter for inverting an output of the first latch unit;
a second inverter for inverting an output of the second latch unit;
a first logic gate for performing an AND operation on outputs of the first inverter and the second inverter, thereby outputting a first timing control signal;
a second logic gate for performing an AND operation on outputs of the first latch unit and the second inverter, thereby outputting a second timing control signal; and
a third logic gate for performing an AND operation on outputs of the first inverter and the second latch unit, thereby outputting a third timing control signal.

8. The semiconductor memory device of claim 7, wherein the auto-precharge operation is performed one clock later from input time of data corresponding to a write command in response to the first timing control signal.

9. The semiconductor memory device of claim 7, wherein the auto-precharge operation is performed two clocks later from input time of data corresponding to a write command in response to the second timing control signal.

10. The semiconductor memory device of claim 7, wherein the auto-precharge operation is performed three clocks later from input time of data corresponding to a write command in response to the third timing control signal.
